(19) United States
(12) Patent Application Publication
(10) Pub. No.: US 2012/0199847 A1
(43) Pub. Date: Aug. 9, 2012

(54) SEMICONDUCTOR DEVICE

(75) Inventor: Kazutaka Takagi, Kawasaki-shi (JP)

(73) Assignee: Kabushiki Kaisha Toshiba, Tokyo (JP)

(21) Appl. No.: 13/352,810

(22) Filed: Jan. 18, 2012

(30) Foreign Application Priority Data
Feb. 8, 2011 (JP) 2011-024948
Feb. 8, 2011 (JP) 2011-024949
Jan. 10, 2012 (JP) 2012-002199

(51) Int. Cl. H01L 29/16; H01L 29/78; H01L 29/20

(52) U.S. Cl. 257/77; 257/76; 257/279; 257/E29.089; 257/E29.082; 257/E29.255

(57) ABSTRACT

A semiconductor device according to one embodiment includes: a unit FET cell(s) having multi-fingers composed of parallel connection of a unit finger; a designated gate bus line(s) configured to connect gate fingers of the unit FET cell having multi-fingers in parallel; and a gate extracting line(s) configured to be connected to the designated gate bus line, wherein a connecting point between the gate extracting line and the designated gate bus line is shifted from a center in the unit FET cell having multi-fingers, and thereby the numbers of the gate fingers connected to one side of the connecting point is more than the number of the gate fingers connected to another side of the connecting point.

### CROSS REFERENCE TO RELATED APPLICATIONS

This application is based upon and claims the benefit of priority from prior Japanese Patent Application Nos. P2011-024948 and P2011-024949 both filed on Feb. 8, 2011, and P2012-002199 filed on Jan. 10, 2012, the entire contents of which are incorporated herein by reference.

### FIELD

Embodiments described herein generally relate to a semiconductor device.

### BACKGROUND

In recent years, a Gallium Nitride (GaN) based High Electron Mobility Transistor (HEMT) has been turned into actual utilization.

Conventional high frequency semiconductor devices, such as GaN based HEMT, includes a multi-FET cell configuration which disposes in parallel a plurality of FET cells composed of a micro Field Effect Transistor (FET), and is configured to insert a suitable balancing resistance between cells into between gate inputs of each FET cell in order to suppress a loop oscillation between FET cells.

### BRIEF DESCRIPTION OF THE DRAWINGS

FIG. 1A is an enlarged drawing showing a schematic planar pattern configuration of a semiconductor device according to a first embodiment, and FIG. 1B is an enlarged drawing of J portion shown in FIG. 1A.

FIG. 2 is an enlarged drawing showing a schematic planar pattern configuration of a semiconductor device according to a first comparative example.

FIG. 3 is a constructional example 1 of the semiconductor device according to the first embodiment, and is a schematic cross-sectional configuration diagram taken in the line I-I of FIG. 1B.

FIG. 4 is a constructional example 2 of the semiconductor device according to the first embodiment, and is a schematic cross-sectional configuration diagram taken in the line I-I of FIG. 1B.

FIG. 5 is a constructional example 3 of the semiconductor device according to the first embodiment, and is a schematic cross-sectional configuration diagram taken in the line I-I of FIG. 1B.

FIG. 6 is a constructional example 4 of the semiconductor device according to the first embodiment, and is a schematic cross-sectional configuration diagram taken in the line I-I of FIG. 1B.

FIG. 7A is a schematic circuit configuration diagram for explaining a loop oscillation in one cell in the semiconductor device according to the first embodiment, and FIG. 7B is a schematic circuit configuration diagram for explaining suppression effect of the loop oscillation in one cell.

FIG. 8 is a configuration diagram showing a schematic equivalent circuit of a semiconductor amplifier to which the semiconductor device according to the first embodiment is applied.

FIG. 9A shows a loop gain calculating circuit in one cell configured to attach a circulator to an input side of a loop in one cell in the semiconductor amplifier to which the semiconductor device according to the first embodiment is applied, and FIG. 9B shows a loop gain calculating circuit in one cell configured to attach the circulator to an output side of the loop in one cell in the semiconductor amplifier to which the semiconductor device according to the first embodiment is applied.

FIG. 10A is a schematic planar pattern configuration diagram showing a unit cell having multi-fingers in the semiconductor device according to the first embodiment, FIG. 10B is a schematic planar pattern configuration diagram showing the unit cell having multi-fingers of FIG. 10A divided into ½ cell, and FIG. 10C is a configuration diagram of a schematic equivalent circuit corresponding to FIG. 10A and FIG. 10B.

FIG. 11A is a schematic planar pattern configuration diagram showing a portion of two unit cells of the unit cells having multi-fingers in the semiconductor device according to the first embodiment, and FIG. 11B is a configuration diagram showing a schematic loop equivalent circuit corresponding to FIG. 11A.

FIG. 12A is a schematic planar pattern configuration diagram showing a unit cell having multi-fingers in the semiconductor device according to the first comparative example, FIG. 12B is a schematic planar pattern configuration diagram showing the unit cell having multi-fingers of FIG. 12A divided into ½ cell, and FIG. 12C is a configuration diagram of a schematic equivalent circuit corresponding to FIG. 12A and FIG. 12B.

FIG. 13A is a schematic planar pattern configuration diagram showing a portion of two unit cells of the unit cells having multi-fingers in the semiconductor device according to the first comparative example, and FIG. 13B is a configuration diagram showing a schematic loop equivalent circuit corresponding to FIG. 13A.

FIG. 14A is an enlarged drawing showing a schematic planar pattern configuration of a semiconductor device according to a second embodiment, and FIG. 14B is an enlarged drawing of J portion shown in FIG. 14A.

FIG. 15 is a schematic circuit configuration diagram for explaining suppression effect of a loop oscillation in one cell focusing attention on a specific FET cell FET (n), in the semiconductor device according to the second embodiment.

FIG. 16 is an enlarged drawing showing a schematic planar pattern configuration of a semiconductor device according to a third embodiment.

FIG. 17 is an enlarged drawing showing a schematic planar pattern configuration of a semiconductor device according to a fourth embodiment.

### DETAILED DESCRIPTION

Hereinafter, embodiments will be described with reference to drawings.

According to one embodiment, a semiconductor device includes a unit FET cell(s) having multi-fingers, a designated gate bus line(s), and a gate extracting line(s). The unit FET cell having multi-fingers is composed of parallel connection of unit fingers. The designated gate bus line connects the gate fingers of the unit FET cell having multi-fingers in parallel. The gate extracting line is connected to the designated gate bus line. In this case, a connecting point between the gate extracting line and the designated gate bus line is shifted from a center in the unit FET cell having multi-fingers, and thereby the number of the gate fingers connected to one side of the connecting point is more than the number of the gate fingers connected to another side of the connecting point.

Also, in this case, as for the unit FET cell having multi-fingers, the way the gate fingers are bundled or the way the source fingers are bundled is shifted against the way the drain fingers are bundled.

### First Embodiment

### Plane Pattern Configuration

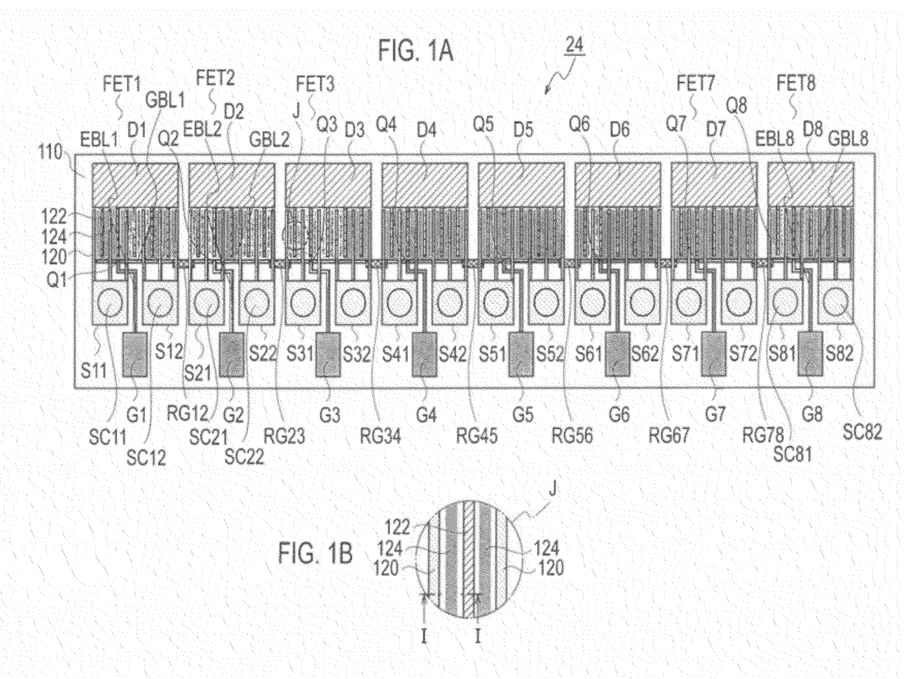

A schematic planar pattern configuration of a semiconductor device 24 according to a first embodiment is expressed as shown in FIG. 1A, and an enlarged drawing of J portion shown in FIG. 1A is expressed as shown in FIG. 1B.

As shown in FIG. 1, the semiconductor device 24 according to the first embodiment includes: unit FET cells FET1, FET2, FET3, . . . , FET8 having multi-fingers composed of parallel connection of unit fingers; designated gate bus lines GBL1, GBL2, GBL3, . . . , GBL8 configured to connect gate fingers of the unit FET cells FET1, FET2, FET3, . . . , FET8 having multi-fingers in parallel, respectively; and gate extracting lines EBL1, EBL2, EBL3, . . . , EBL8 configured to be connected to the designated gate bus lines GBL1, GBL2, GBL3, . . . , GBL8, respectively. Connecting points Q1, Q2, Q3, . . . , Q8 between the gate extracting lines EBL1, EBL2, EBL3, EBL8 and the designated gate bus lines GBL1, GBL2, GBL3, . . . , GBL8 are shifted from centers in the unit FET cells FET1, FET2, FET3, . . . , FET8 having multi-fingers, respectively, and thereby the number of the gate fingers connected to one side of the respective connecting points Q1, Q2, Q3, . . . , Q8 is more than the number of the gate fingers connected to another side of the respective connecting points Q1, Q2, Q3, . . . , Q8.

As shown in FIG. 1, the semiconductor devices 24 according to the first embodiment, the respective connecting points Q1, Q2, Q3, . . . , Q8 between the respective gate extracting lines EBL1, EBL2, EBL3, . . . , EBL8 and the respective designated gate bus lines GBL1, GBL2, GBL3, . . . , GBL8 are shifted from the centers in the respective FET cells FET1, FET2, FET3, . . . , FET8, and thereby the respective gate extracting lines EBL1, EBL2, EBL3, . . . , EBL8 appear as a load for an oscillating loop. As a result, since an oscillating condition of oscillation in one FET cell is not satisfied, and therefore the oscillation in one cell can be suppressed.

Also, as shown in FIG. 1, in the semiconductor device 24 according to the first embodiment, the plurality of unit FET cells FET1, FET2, FET3, . . . , FET8 having multi-fingers include: a substrate 110; a gate finger electrode 124, a source finger electrode 120, and a drain finger electrode 122 which are configured to be disposed on a first surface of the substrate 110 and configured to have a plurality of fingers, respectively; and gate terminal electrodes G1, G2, . . . , G8, source terminal electrodes S11, S12, S21, S22, S31, S32, . . . , S81, and S82 and drain terminal electrodes D1, D2, D3, . . . , D8 which are configured to be disposed on the first surface of the substrate 100 and configured to tie the plurality of the fingers for every the gate finger electrode 124, the source finger electrode 126, and the drain finger electrode 122, respectively. Each of the gate terminal electrodes G1, G2, . . . , G8 is connected to an input matching circuit by a bonding wire etc., and each of the drain terminal electrodes D1, D2, . . . , D8 is connected to an output matching circuit by a bonding wire etc.

Also, in the semiconductor device 24 according to the first embodiment, the respective gate extracting lines EBL1, EBL2, EBL3, . . . , EBL8 connect between the respective designated gate bus lines GBL1, GBL2, GBL3, . . . , GBL8, and the respective gate terminal electrodes G1, G2, G3, . . . , G8.

Also, as shown in FIG. 1, the semiconductor device 24 according to the first embodiment may include: VIA holes SC11, SC12, SC21, SC22, SC31, SC32, . . . , SC81, and SC82 configured to be disposed at lower parts of the source terminal electrodes S11, S12, S21, S22, S31, S32, . . . , S81, and S82, respectively; and a ground electrode (not shown) configured to be disposed on a second surface of opposite side of the first surface of the substrate 110, and configured to be connected via the VIA holes SC11, SC12, SC21, SC22, SC31, SC32, . . . , SC81, and SC82 with the source terminal electrodes S11, S12, S21, S22, S31, S32, . . . , S81, and S82, respectively. The source terminal electrodes S11, S12, S21, S22, . . . , S81, and S82 are connected to the ground electrode via barrier metal layers (not shown) formed on surfaces of internal walls of the VIA holes SC11, SC12, SC21, SC22, . . . , SC81, and SC82, respectively, and via filling metal layers (not shown) formed on the barrier metal layers configured to fill the VIA holes, respectively.

Also, in the semiconductor device 24 according to the first embodiment, as shown in FIG. 1, the unit FET cells FET1, FET2, FET3, . . . , FET8 having multi-fingers may be connected in parallel.

Furthermore, in the semiconductor device 24 according to the first embodiment, as shown in FIG. 1, balancing resistances RG12, RG23, RG34, . . . , RG78 between cells for suppressing a loop oscillation between cells may be disposed respectively between the designated gate bus lines GBL1 and GBL2, between GBL2 and GBL3, between GBL3 and GBL4, . . . , between GBL7 and GBL8 of the unit FET cells FET1, FET2, FET3, . . . , FET8 having multi-fingers which are mutually adjoining.

### First Comparative Example

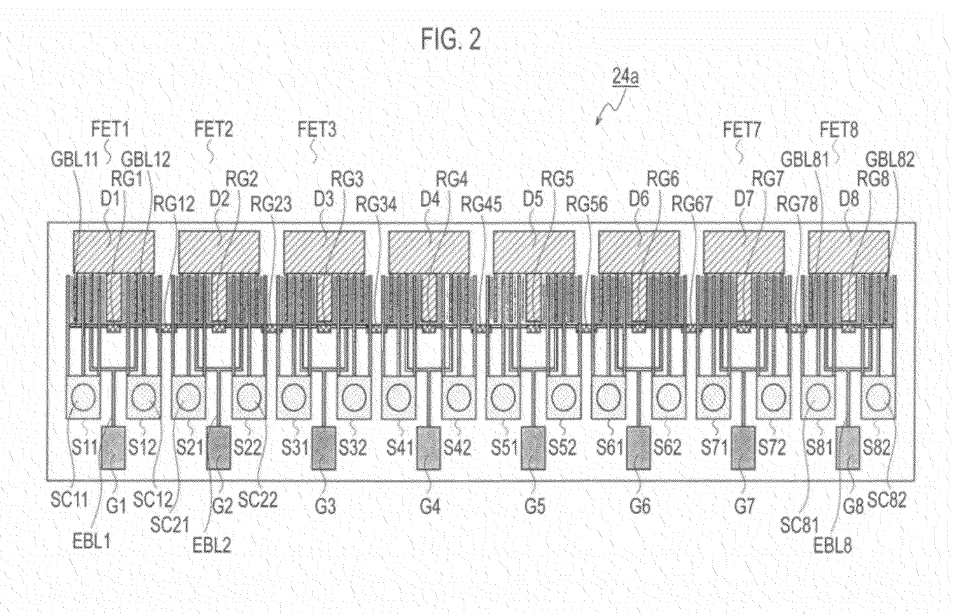

A schematic planar pattern configuration of a semiconductor device 24a according to a first comparative example is expressed as shown in FIG. 2. In the semiconductor device 24a according to the first comparative example, each of the FET cells FET1, FET2, FET3, . . . , FET8 is divided into two parts, each of the balancing resistances RG1, RG2, RG3, . . . , RG8 in one cell is inserted between gate inputs of each the ½ FET cell divided into two parts, and thereby the loop oscillation in one cell can be suppressed. However, according to the first comparative example, as shown in FIG. 2, space for disposing the balancing resistances RG1, RG2, RG3, . . . , RG8 in one cell is required, and therefore an area of the semiconductor device 24a is increased.

### (Element Structure)

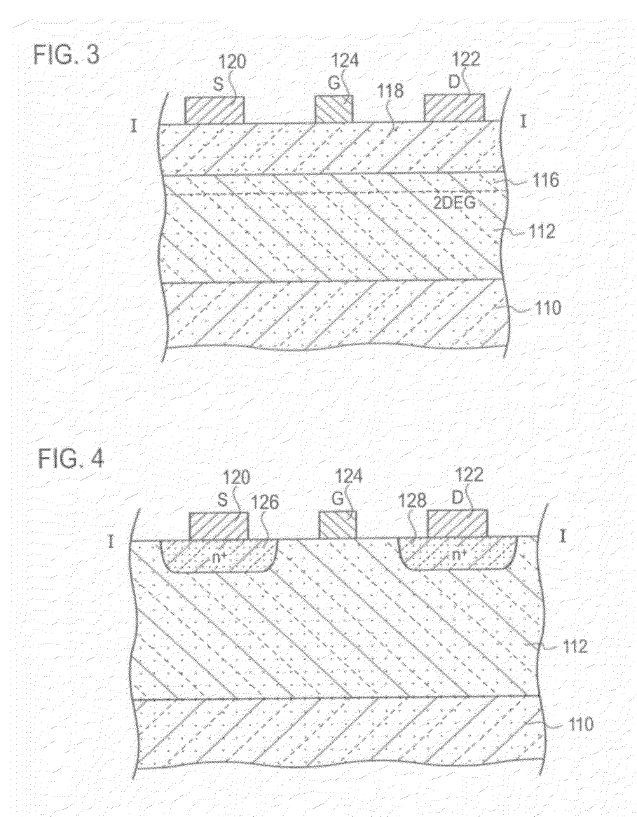

Schematic cross-sectional constructional examples 1-4 taken in the line I-I of FIG. 1B which are element structures of the semiconductor device 24 according to the first embodiment are expressed as shown in FIG. 3 to FIG. 6, respectively.

The semiconductor device 24 according to the first embodiment includes: a substrate 110; a nitride based compound semiconductor layer 112 configured to be disposed on the substrate 110; an aluminum gallium nitride layer (AlₓGa₁₋ₓN) (where 0.1<=x<=1) 118 configured to be disposed on the nitride based compound semiconductor layer 112; and a source finger electrode 120, a gate finger electrode 124, and a drain finger electrode 122 which are configured to be disposed on the aluminum gallium nitride layer (AlₓGa₁₋ₓN) (where 0.1<=x<=1) 118. A two dimensional electron gas (2DEG) layer 116 is formed in an interface between the nitride based compound semiconductor layer 112 and the aluminum gallium nitride layer (AlₓGa₁₋ₓN) (where 0.1<=x<=1) 118.

The substrate 110 may be provided with any one of an SiC substrate, a GaAs substrate, a GaN substrate, a substrates in which the GaN epitaxial layer is formed on the SiC substrate, a substrate in which the GaN epitaxial layer is formed on the Si substrate, a substrate in which the heterojunction epitaxial layer composed of GaN/GaAlN is formed on the SiC substrate, a substrate in which the GaN epitaxial layer is formed on the sapphire substrate, a sapphire substrate or a diamond substrate, and a semi-insulating substrate.

### Constructional Example 1

As shown in FIG. 3, a constructional example 1 of the FET cell of the semiconductor device 24 according to the first embodiment as a schematic cross section configuration taken in the line I-I of FIG. 1B includes: a semi-insulating substrate 110; a nitride based compound semiconductor layer 112 configured to be disposed on the semi-insulating substrate 110; an aluminum gallium nitride layer (AlₓGa₁₋ₓN) (where 0.1<=x<=1) 118 configured to be disposed on the nitride based compound semiconductor layer 112; and a source finger electrode 120, a gate finger electrode 124, and a drain finger electrode 122 which are configured to be disposed on the aluminum gallium nitride layer (AlₓGa₁₋ₓN) (where 0.1<=x<=1) 118. The two dimensional electron gas (2DEG) layer 116 is formed in an interface between the nitride based compound semiconductor layer 112 and the aluminum gallium nitride layer (AlₓGa₁₋ₓN) (where 0.1<=x<=1) 118. FIG. 3 shows a Hetero-Junction Field Effect Transistor (HFET) or a High Electron Mobility Transistor (HEMT) as the constructional example 1 according to the first embodiment.

### Constructional Example 2

As shown in FIG. 4, a constructional example 2 of the FET cell of the semiconductor device 24 according to the first embodiment as a schematic cross section configuration taken in the line I-I of FIG. 1B includes: a semi-insulating substrate 110; a nitride based compound semiconductor layer 112 configured to be disposed on the semi-insulating substrate 110; a source region 126 and a drain region 128 which are configured to be disposed on the nitride based compound semiconductor layer 112; and a source finger electrode 120 configured to be disposed on the source region 126, a gate finger electrode 124 configured to be disposed on the nitride based compound semiconductor layer 112, and a drain finger electrode 122 configured to be disposed on the drain region 128. Schottky contact is formed in an interface between the nitride based compound semiconductor layer 112 and the gate finger electrode 124. FIG. 4 shows a Metal Semiconductor Field Effect Transistor (MESFET) as the constructional example 2 according to the first embodiment.

### Constructional Example 3

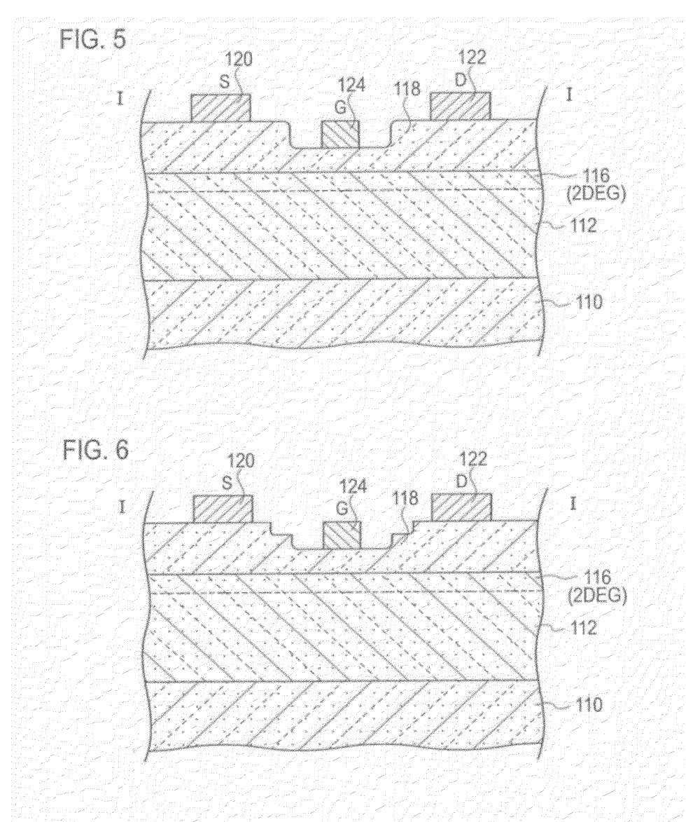

As shown in FIG. 5, a constructional example 3 of the FET cell of the semiconductor device 24 according to the first embodiment as a schematic cross section configuration taken in the line I-I of FIG. 1B includes: a semi-insulating substrate 110; a nitride based compound semiconductor layer 112 configured to be disposed on the semi-insulating substrate 110; an aluminum gallium nitride layer (AlₓGa₁₋ₓN) (where 0.1<=x<=1) 118 configured to be disposed on the nitride based compound semiconductor layer 112; a source finger electrode 120 and a drain finger electrode 122 which are configured to be disposed on the aluminum gallium nitride layer (AlₓGa₁₋ₓN) (where 0.1<=x<=1) 118; and a gate finger electrode 124 configured to be disposed at a recessed part on the aluminum gallium nitride layer (AlₓGa₁₋ₓN) (where 0.1<=x<=1) 118. A 2DEG layer 116 is formed in an interface between the nitride based compound semiconductor layer 112 and the aluminum gallium nitride layer (AlₓGa₁₋ₓN) (where 0.1<=x<=1) 118. FIG. 5 shows HFET or HEMT as the constructional example 3 according to the first embodiment.

### Constructional Example 4

As shown in FIG. 6, a constructional example 4 of the FET cell of the semiconductor device 24 according to the first embodiment as a schematic cross section configuration taken in the line I-I of FIG. 1B includes: a semi-insulating substrate 110; a nitride based compound semiconductor layer 112 configured to be disposed on the semi-insulating substrate 110; an aluminum gallium nitride layer (AlₓGa₁₋ₓN) (where 0.1<=x<=1) 118 configured to be disposed on the nitride based compound semiconductor layer 112; a source finger electrode 120 and a drain finger electrode 122 which are configured to be disposed on the aluminum gallium nitride layer (AlₓGa₁₋ₓN) (where 0.1<=x<=1) 118; and a gate finger electrode 124 configured to be disposed at a two-step recessed part on the aluminum gallium nitride layer (AlₓGa₁₋ₓN) (where 0.1<=x<=1) 118. A 2DEG layer 116 is formed in an interface between the nitride based compound semiconductor layer 112 and the aluminum gallium nitride layer (AlₓGa₁₋ₓN) (where 0.1<=x<=1) 118. FIG. 6 shows HFET or HEMT as the constructional example 4 according to the first embodiment.

Moreover, in the above-mentioned constructional examples 1-4 according to the first embodiment, the nitride based compound semiconductor layer 112 except an active area is electrically used as an inactivity isolation region. In this case, the active area is composed of the 2DEG layer 116 directly under the source finger electrode 120, the gate finger electrode 124, and the drain finger electrode 122, and the 2DEG layer 116 between the source finger electrode 120 and the gate finger electrode 124 and between the drain finger electrode 122 and the gate finger electrode 124.

As another fabrication method of the isolation region, it can also form by ion implantation to a part of depth direction of the aluminum gallium nitride layer (AlₓGa₁₋ₓN) (where 0.1<=x<=1) 118 and the nitride based compound semiconductor layer 112. As ion species, nitrogen (N), argon (Ar), etc. are applicable, for example. Moreover, the amount of dosage with the ion implantation is about 1×10¹⁴ (ions/cm²), for example, and accelerating energy is about 100 keV to 200 keV, for example.

On the isolation region and the device surface, an insulating layer for passivation (not shown) is formed. As the insulating layer, it can be formed of a nitride film, an alumina (Al₂O₂) film, an oxide film (SiO₂), an oxynitriding film (SiON), etc. deposited by a Plasma Enhanced Chemical Vapor Deposition (PECVD) method, for example.

The source finger electrode 120 and the drain finger electrode 122 are formed of Ti/Al etc., for example. The gate finger electrode 124 can be formed, for example of Ni/Au etc.

In addition, in the semiconductor device 24 according to the first embodiment, the pattern length of longitudinal direction of the gate finger electrode 124, the source finger electrode 120, and the drain finger electrode 122 is set up to be shorter as operating frequency becomes high such as microwave/millimeter wave/submillimeter wave. For example, the pattern length is about 100 μm in the microwave band, and is about 25 μm to 50 μm in the millimeter wave band.

Also, the width of the source finger electrode 120 is about 40 μm, for example, and the width of the source terminal electrode S11, S12, S21, S22, . . . , S101, and S102 is about 100 μm, for example. Also, the width of the drain terminal electrode D1, D2, D3, . . . , D8 is about 100 μm, for example. Yet also, the formation width of the VIA holes SC11, SC12, SC21, SC22, . . . , SC101, and SC102 is about 10 μm to about 40 μm, for example.

### (Loop Oscillation in One Cell)

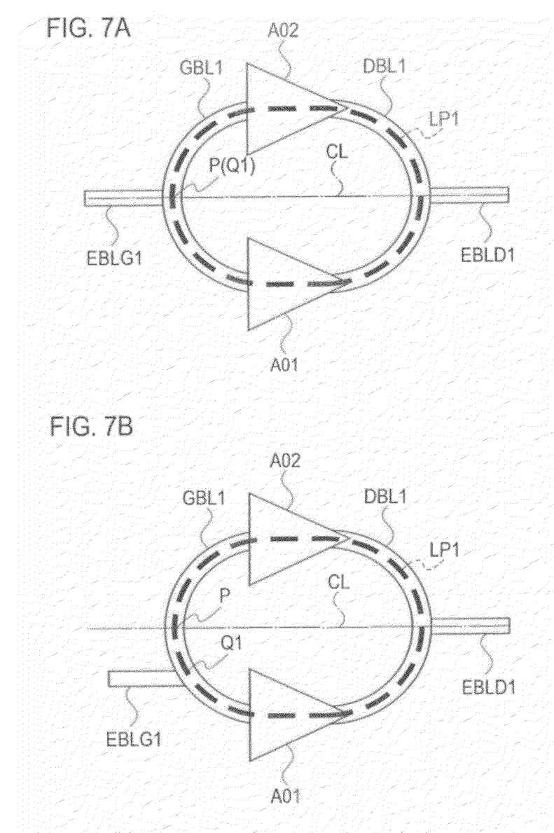

In the semiconductor device according to the first embodiment, a schematic circuit configuration for explaining a loop oscillation in one cell is expressed as shown in FIG. 7A, and a schematic circuit configuration for explaining suppression effect of the loop oscillation in one cell is expressed as shown in FIG. 7B.

The unit FET cell having multi-fingers is expressed by ½ FET cells A01 and A02, as shown in FIG. 7A and FIG. 7B. As shown in FIG. 7A and FIG. 7B, a loop LP1 in one cell includes: ½ FET cells A01 and A02 used in a pair; a designated gate bus line GBL1 configured to connect a gate of the ½ FET cell A01 and a gate of the ½ FET cell A02; and a designated drain bus line DBL1 configured to connect a drain of the ½ FET cell A01 and a drain of the ½ FET cell A02.

In the example of FIG. 7A, a gate extracting line EBLG1 and a drain extracting line EBLD1 are disposed on a center line CL of the loop LP1 in one cell composed of the ½ FET cells A01 and A02, and a cross over point P between the center line CL and the loop LP1 in one cell is coincided with a connecting point Q1 between the gate extracting line EBLG1 and the designated gate bus line GBL1.

On the other hand, in the example of FIG. 7B, the drain extracting line EBLD1 is disposed on the center line CL of the loop LP1 in one cell composed of the ½ FET cells A01 and A02, and the connecting point Q1 between the gate extracting line EBLG1 and the designated gate bus line GBL1 is disposed at a position shifted in a ½ FET cell A01 direction on the loop LP1 in one cell from the cross over point P between the center line CL and the loop LP1 in one cell.

In the example of FIG. 7A, the loop LP1 in one cell composes an oscillating loop and becomes a node of the standing wave on the cross over point P between the center line CL of the loop LP1 in one cell composed of the ½ FET cells A01 and A02 and the loop LP1 in one cell, and an outside observed from the cross over point P appears as total reflection. As a result, the gate extracting line EBLG1 connected to the cross over point P does not become a load for the loop oscillation in one cell. That is, the loop oscillation in one cell occurs.

On the other hand, as shown in FIG. 7B, since the gate extracting line EBLG1 connected to the connection point Q1 dislocated from the cross over point P between the center line CL of the loop LP1 in one cell composed of the ½ FET cells A01 and A02 and the loop LP1 in one cell becomes the load for the loop oscillation in one cell, an oscillating condition is not satisfied and therefore the loop oscillation in one cell can be suppressed.

### (Circuit Configuration of Semiconductor Amplifier)

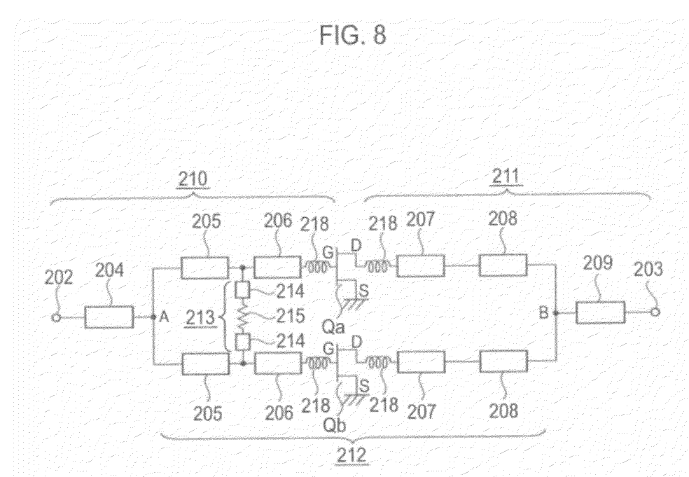

A configuration of a schematic equivalent circuit of a semiconductor amplifier to which the semiconductor device according to the first embodiment is applied is expressed as shown in FIG. 8. In FIG. 8, reference numerals Qa and Qb denote source grounded ½ FET cells, respectively, and the respective source grounded ½ FET cells Qa and Qb include a gate terminal electrode G, a drain terminal electrode D, and a source terminal electrode S. The ½ FET cells Qa and Qb are equivalent to cells after the unit FET cell having multi-fingers is divided into two parts, respectively, and correspond to the ½ FET cells A01 and A02 in FIG. 7A and FIG. 7B, respectively. Moreover, in FIG. 8, reference numeral 202 denotes an input terminal of the amplifier, reference numeral 203 denotes an output terminal of the amplifier, reference numeral 210 denotes an input matching circuit, and reference numeral 211 denotes an output matching circuit.

Reference numerals 204, 205, 206, 207, 208, and 209 denotes transmission lines, respectively, and source grounded ½ FET cells Qa or Qb in this order is connected in parallel between two couples of the transmission lines 204 and 209. That is, the transmission line from the transmission line 204 connected to the input terminal 202 branches to two-way at point A, and then two couples of the transmission lines 205 and 206 connected in series are connected to a gate terminal electrode G of the ½ FET cell Qa or Qb in series via the bonding wire 218. Furthermore, from drain terminal electrode D of the ½ FET cell Qa or Qb, the transmission lines 207 and 208 are also connected in series via the bonding wire 218, other ends of two couples of the transmission lines 208 are connected in common to one end of the transmission line 209 at point B, and other end of the transmission line 209 is connected to the output terminal 203. The input matching circuit 210 is composed of the above-mentioned transmission lines 204, 205, and 206, respectively, and the output matching circuit 211 composed of the above-mentioned transmission lines 207, 208, and 209, respectively.

In the amplifier, a loop circuit 212 in one cell is composed of the transmission lines 205, 206, 207 and 208 and the ½ FET cells Qa and Qb configured to operate in parallel. Reference numeral 213 denotes an equivalent resistance circuit. The equivalent resistance circuit 213 is composed of a transmission line 214 for connection and a balance equivalent resistance 215 in one cell, and is connected to a predetermined position which opposes in the input matching circuit of the above-mentioned loop circuit 212 in one cell.

Hereinafter, operation will be explained. In FIG. 8, a fundamental wave, i.e., a signal component of frequency f₀, is input from the input terminal 202, and then is distributed at the point A to be input into the respective ½ FET cells Qa and Qb connected in parallel. The signals amplified in the respective ½ FET cells Qa and Qb are synthesized at the point B, and then the synthesized signal is output from the output terminal 203.

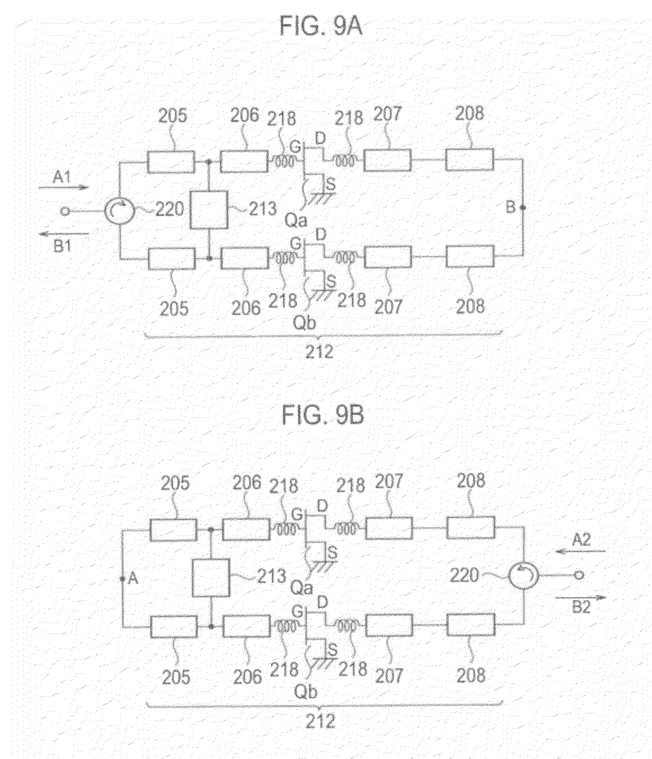

In the semiconductor amplifier to which the semiconductor device according to the first embodiment is applied, a loop gain calculating circuit in one cell configured to attach a circulator to the input side of the loop circuit 212 in one cell is expressed as shown in FIG. 9A, and a loop gain calculating circuit in one cell configured to attach a circulator to the output side of the loop circuit 212 in one cell is expressed as shown in FIG. 9B.

Here, in the loop circuit 212 in one cell shown in FIG. 9A and FIG. 9B, a loop oscillating condition in one cell is expressed by the following formulas (1) and (2).

|B1/A1|>=1 and ∠(B1/A1)=2 nπ (1)

|B2/A2|>=1 and ∠(B2/A2)=2 mπ (2)

where m and n are integers.

In this case, the terms A1 and B1 indicate an input traveling wave in the input side and an output traveling wave from the loop circuit 212 in one cell, respectively, in the case of attaching tentatively the ideal circulator 220 to the input side of the loop circuit 212 in one cell shown in FIG. 9A, as paper calculating. Also, the terms A2 and B2 indicate an input traveling wave in the output side and an output traveling wave from the loop circuit 212 in one cell, respectively, in the case of attaching tentatively the ideal circulator 220 to the output side of the loop circuit 212 in one cell shown in FIG. 9B.

In order for an oscillation to occur, it is required to satisfy ∠(B1/A1)=2 nπ. The above state corresponds to a state where a standing wave stands between the point A and the point B. At the point A and the point B, the output traveling wave B1 and the input traveling wave A1 are canceled each other, and then there is no voltage amplitude, that is, it becomes a position of a node of the standing wave. The node of the standing wave corresponds to a position with a voltage of 0V, and the position with the voltage of 0V becomes equivalent to a state where it is grounded.

Therefore, as already explained in FIG. 7A, the transmission line composed of the gate extracting line EBLG1 connected to the node of the standing wave, i.e., the position equivalent to ground, does not appear as the load for the frequency component in which the oscillation has occurred in the loop LP1 in one cell.

On the other hand, voltage has occurred on the loop in one cell except the position acting as the node. Therefore, as already explained in FIG. 7B, the transmission line composed of the gate extracting line EBLG1 connected except the node appears as the load for the frequency component in which the oscillation has occurred in the loop LP1 in one cell, and its phase changes. As a result, ∠(B1/A1)=2 nπ is satisfied. That is, since the oscillating condition is not satisfied, the loop oscillation in the multi-finger FET cell can be suppressed.

In the semiconductor device according to the first embodiment, the value of the balance equivalent resistance 215 in one cell which is a level that the suppression effect of the loop oscillation in the unit FET cell having multi-fingers occurs is the same grade as the impedance of the transmission line composed of gate extracting line EBLG1. Accordingly, in the semiconductor device according to the first embodiment, the loop oscillation can be suppressed without disposing the balancing resistance RG1 in one cell as the first comparative example shown in FIG. 2, and the area is also not increased.

### (Cell Configuration)

—Unit Cell Configuration—

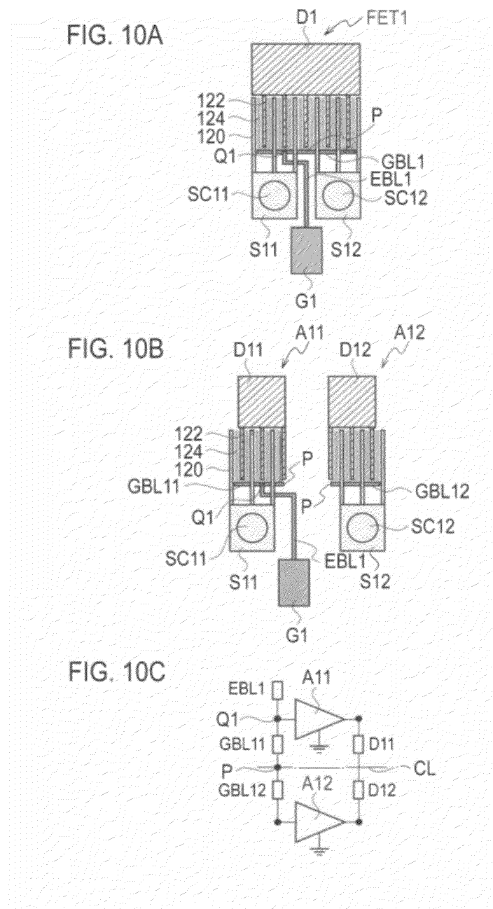

In the semiconductor device according to the first embodiment, a schematic planar pattern configuration of the unit cell FET1 having multi-fingers is expressed, as shown in FIG. 10A, a schematic planar pattern configuration with which the unit cell FET1 having multi-fingers of FIG. 10A is divided into ½ FET cells A11 and A12 is expressed as shown in FIG. 10B, and a configuration of schematic equivalent circuit corresponding to FIG. 10A and FIG. 10B is expressed as shown in FIG. 10C. FIG. 10A corresponds to the unit cell FET1 having multi-fingers portion of FIG. 1. In FIG. 10A, the designated gate bus line GBL1 and the gate extracting line EBL1 are connected at the connecting point Q1. In unit cell FET1 having multi-fingers shown in FIG. 10A, the number of the gate fingers connected to left-hand side of the connecting point Q1 is configured to be less than the number of the gate fingers connected to right-hand side of the connecting point Q1.

In the schematic planar pattern configuration with which the unit cell having multi-fingers of FIG. 10A is divided into the ½ cell, since the designated gate bus line GBL1 and the gate extracting line EBL1 are connected in the connecting point Q1 which is dislocated from the cross over point P between the loop in one cell and the center line CL as shown in FIG. 10B, the gate extracting line EBL1 and the gate terminal electrode G1 are connected to the designated gate bus line GBL11 of left-hand side. Accordingly, as shown in FIG. 10C, the impedance equivalent to the gate extracting line EBL1 and the gate terminal electrode G1 is connected to the connecting point Q1 acting as the input of the ½ FET cell A11.

As shown in FIG. 10A to FIG. 10C, in the semiconductor device according to the first embodiment, voltage has occurred, since the connecting point Q1 does not become a node on the loop in one cell, from the configuration viewpoint of the unit cell FET1 having multi-fingers. Therefore, the transmission line composed of the gate extracting line EBL1 connected except the node appears as the load for the frequency component in which the oscillation has occurred in the loop LP1 in one cell, and its phase changes. As a result, ∠(B1/A1)=2 nπ is not satisfied. That is, since the oscillating condition is not satisfied, the loop oscillation in the multi-finger FET cell can be suppressed.

—Two Unit Cell Configuration—

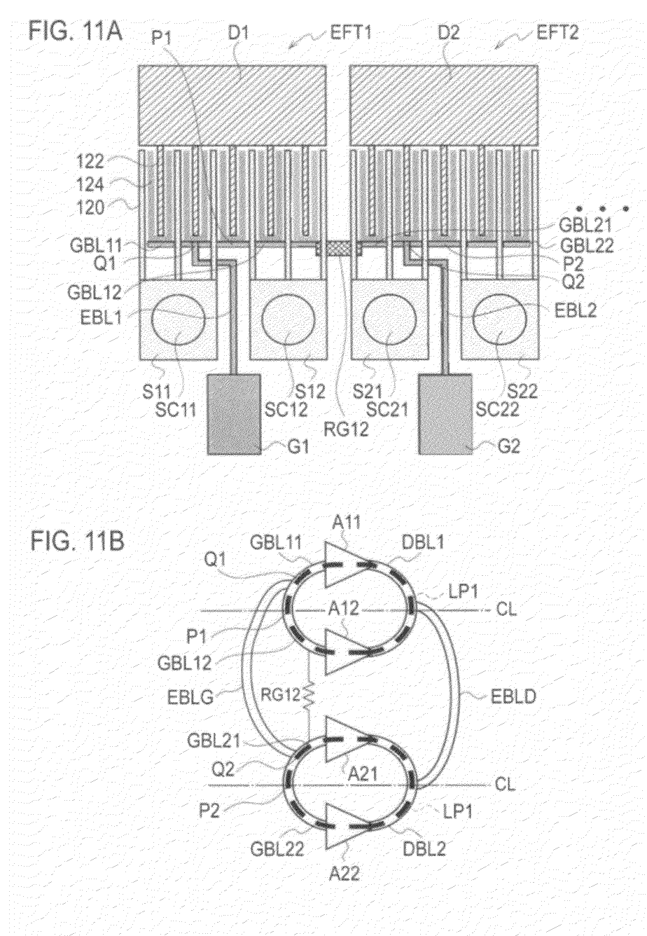

In the semiconductor device according to the first embodiment, a schematic planar pattern configuration of a portion of two unit cell of the unit cells having multi-fingers is expressed as shown in FIG. 11A, and a configuration of a schematic loop equivalent circuit corresponding to FIG. 11A is expressed as shown in FIG. 11B. FIG. 11A corresponds to a two unit cell composed of the unit cells FET1 and FET2 having multi-fingers shown in FIG. 1. In FIG. 11A, the designated gate bus line GBL1 and the gate extracting line EBL1 are connected at the connecting point Q1. In unit cell FET1 having multi-fingers shown in FIG. 11A, the number of the gate fingers connected to left-hand side of the connecting point Q1 is configured to be less than the number of the gate fingers connected to right-hand side of the connecting point Q1. Similarly, the designated gate bus line GBL2 and the gate extracting line EBL2 are connected in the connecting point Q2. In unit cell FET2 having multi-fingers, the number of the gate fingers connected to left-hand side of the connecting point Q2 is configured to be less than the number of the gate fingers connected to right-hand side of the connecting Point Q2.

Also, reference numerals GBL11 and GBL12 denote right and left designated gate bus lines of the connecting point Q1, and reference numerals GBL21 and GBL22 denote right and left designated gate bus lines of the connecting point Q2.

As shown in FIG. 11B, the connecting point Q1 is disposed at a position shifted in the direction of the ½ FET cell A11 on the loop LP1 in one cell from the cross over point P1 between the center line CL and the loop LP1 in one cell, from the configuration viewpoint of the unit cell FET1 having multi-fingers. Similarly, the connecting point Q2 is disposed at a position shifted in the direction of the ½ FET cell A21 on the loop LP1 in one cell from the cross over point P2 between the center line CL and the loop LP1 in one cell, from the configuration viewpoint of the unit cell FET2 having multi-fingers. Therefore, since each the connecting points Q1 and Q2 does not become a node of standing wave, voltage has occurred in each the connecting points Q1 and Q2. Therefore, the transmission line composed of the gate extracting line EBLG (EBL1 and EBL2) connected except the node appears as the load for the frequency component in which the oscillation has occurred in the loop LP1 in one cell, and its phase changes. As a result, ∠(B1/A1)=2 nπ is not satisfied. That is, since the oscillating condition is not satisfied, the loop oscillation in the multi-finger FET cell can be suppressed.

Furthermore, as clearly from FIG. 11A and FIG. 11B, balancing resistance RG12 between cells is connected between the designated gate bus lines GBL12 and GBL21 and thereby the loop oscillation between cells can also be suppressed.

### First Comparative Example

### Unit Cell Configuration

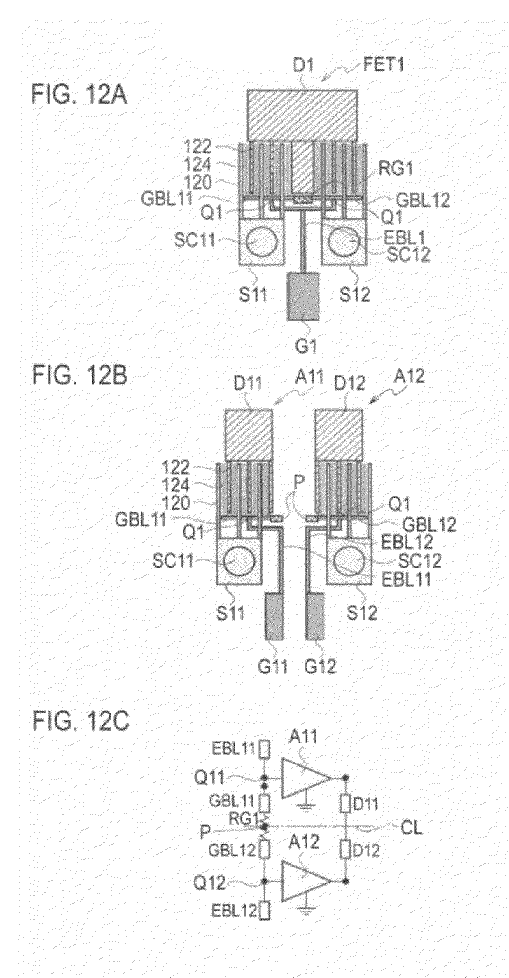

In a semiconductor device according to a first comparative example, a schematic planar pattern configuration of a unit cell having multi-fingers is expressed as shown in FIG. 12A, a schematic planar pattern configuration with which the unit cell having multi-fingers of FIG. 12A is divided into ½ cell is expressed as shown in FIG. 12B, and a configuration of schematic equivalent circuit corresponding to FIG. 12A and FIG. 12B is expressed as shown in FIG. 12C. FIG. 12A corresponds to the unit cell FET1 having multi-fingers portion of the semiconductor device according to the first comparative example of FIG. 2.

In the semiconductor device according to the first comparative example, FET cell FET1 is divided two parts, balancing resistance RG1 in one cell is inserted between gate inputs of each ½ FET cell divided into two parts, and thereby the loop oscillation in one cell can be suppressed.

In FIG. 12A, a designated gate bus line GBL11 and a gate extracting line EBL1 are connected in a connecting point Q1. Similarly, a designated gate bus line GBL12 and the gate extracting line EBL1 are connected in another connecting point Q1.

In the schematic planar pattern configuration with which the unit cell having multi-fingers of FIG. 12A is divided into the ½ cell, as shown in FIG. 12B, the gate extracting line EBL1 is divided into gate extracting lines EBL11 and EBL12, and a gate terminal electrode G1 is divided into gate terminal electrodes G11 and G12. Also, the designated gate bus line GBL11 and the gate extracting line EBL11 are connected in the connecting point Q1. Similarly, the designated gate bus line GBL12 and the gate extracting line EBL12 are connected in the another connecting point Q1. Accordingly, as shown in FIG. 12C, the impedance equivalent to gate extracting line EBL11 and the gate terminal electrode G11 is connected to a connecting point Q11 acting as an input of the ½ FET cell A11, and the impedance equivalent to the gate extracting line EBL12 and the gate terminal electrode G12 is connected to a connecting point Q12 acting as an input of the ½ FET cell A12.

As shown in FIG. 12A to FIG. 12C, in the semiconductor device according to the comparative example, the loop oscillation in the multi-finger FET cell can be suppressed by the balancing resistance RG1 in one cell. However, in the above-mentioned method, as shown in FIG. 12A, space for disposing the balancing resistance RG1 in one cell is required, and therefore area of the FET cell FET 1 is increased.

—Two Unit Cell Configuration—

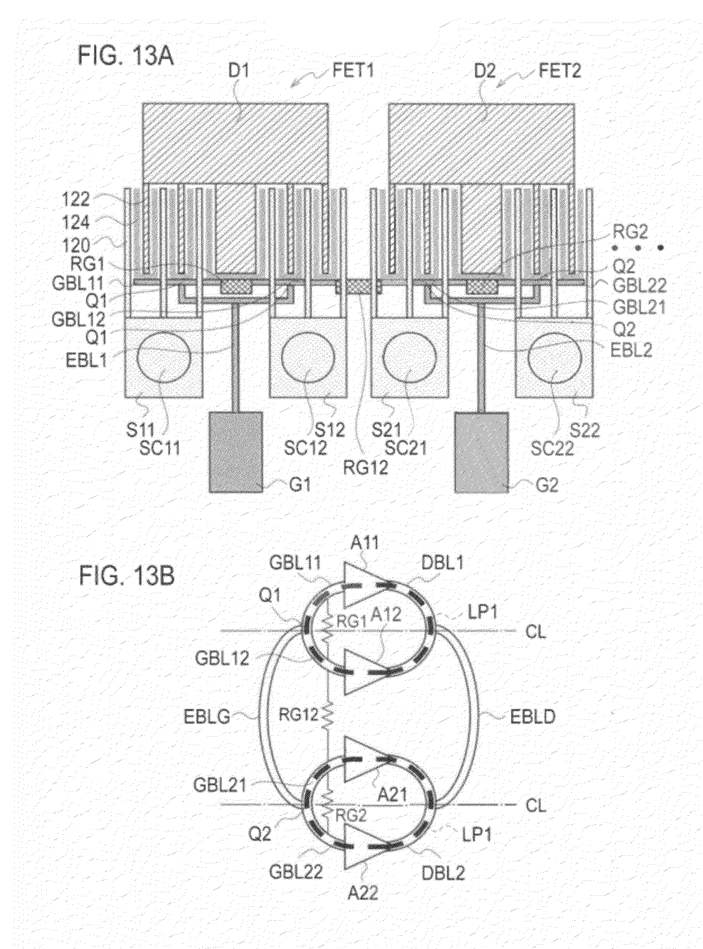

In the semiconductor device according to the first comparative example, a schematic planar pattern configuration of a portion of two unit cell of the unit cells having multi-fingers is expressed as shown in FIG. 13A, and a configuration of a schematic loop equivalent circuit corresponding to FIG. 13A is expressed as shown in FIG. 13B. FIG. 13A corresponds to the two unit cell composed of the unit cells FET1 and FET2 having multi-fingers of FIG. 2. In FIG. 13A, the respective designated gate bus lines GBL11 and GBL12 and the gate extracting line EBL1 are connected at the respective connecting points Q1 and Q1. Similarly, the respective designated gate bus lines GBL21 and GBL22 and the gate extracting line EBL2 are connected at the respective connecting points Q2 and Q2.

As shown in FIG. 13B, for example, the connecting points Q1 and Q2 are disposed at a position mostly corresponding to the cross over point between the center line CL and the loop LP1 in one cell on the loop LP1 in one cell, from the configuration viewpoint of the unit cells FET1 and FET2 having multi-fingers. Therefore, each of the connecting points Q1 and Q2 becomes a node of standing wave substantially. However, a loop oscillation in one cell can be suppressed now at last by inserting the balancing resistance RG1 in one cell between the designated gate bus lines GBL11 and GBL12. Similarly, the loop oscillation in one cell can be suppressed now at last by inserting the balancing resistance RG2 in one cell between the designated gate bus lines GBL21 and GBL22.

Furthermore, as clearly from FIG. 13A and FIG. 13B, although the loop oscillation between cells can also be suppressed by connecting the balancing resistance RG12 between cells into between the designated gate bus lines GBL12 and GBL21, space for disposing the balancing resistances RG1 and RG2 in one cell is required, and therefore area of the FET cells FET1 and FET2 is increased.

According to the semiconductor device according to the first embodiment, the loop oscillation in the multi-finger FET cell can be suppressed, and the increase of chip area can also be suppressed, in a high frequency semiconductor device having a microwave band mainly.

### Second Embodiment

### Plane Pattern Configuration

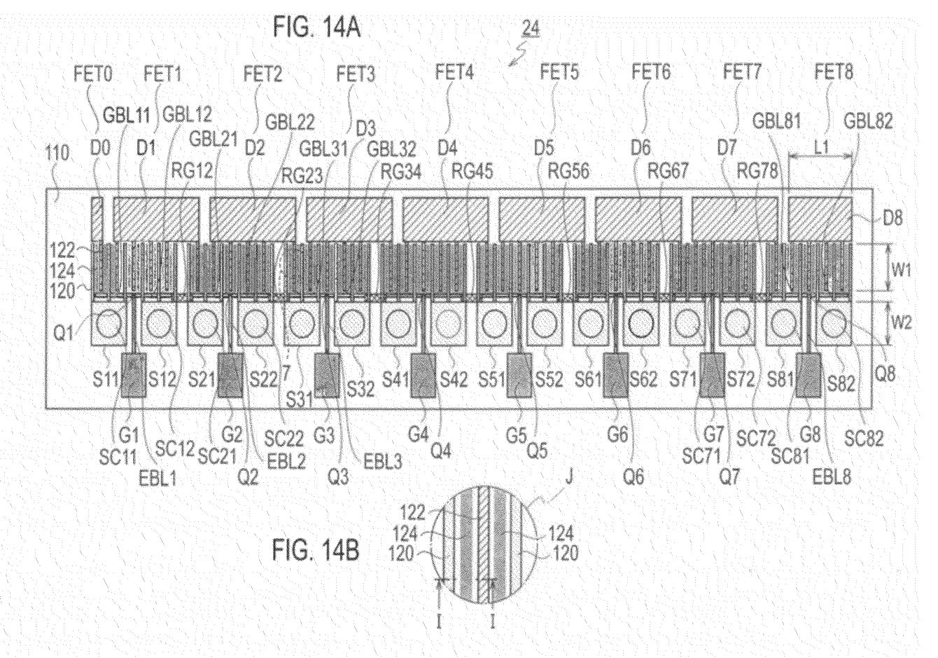

A schematic planar pattern configuration of a semiconductor device 24 according to a second embodiment is expressed as shown in FIG. 14A, and an enlarged drawing of J portion shown in FIG. 14A is expressed as shown in FIG. 14B.

As shown in FIG. 14, the semiconductor device 24 according to the second embodiment includes: unit FET cells FET1, FET2, FET3, . . . , FET8 having multi-fingers composed of parallel connection of unit fingers; designated gate bus lines GBL1, GBL2, GBL3, . . . , GBL8 configured to connect the gate fingers of the unit FET cells FET1, FET2, FET3, . . . , FET8 having multi-fingers in parallel, respectively; and gate extracting lines EBL1, EBL2, EBL3, . . . , EBL8 configured to be connected to the designated gate bus lines GBL1, GBL2, GBL3, . . . , GBL8, respectively. As for the respective unit FET cells FET1, FET2, FET3, . . . , FET8 having multi-fingers, the way gate fingers are bundled is shifted against the way the drain fingers are bundled.

In this case, the designated gate bus line GBL1 is expressed by connection between the designated gate bus lines GBL11 and GBL12, the designated gate bus line GBL2 is expressed by connection between the designated gate bus lines GBL21 and GBL22, the designated gate bus line GBL3 is expressed by connection between the designated gate bus lines GBL3 and GBL32, . . . , and the designated gate bus line GBL8 is expressed by connection between the designated gate bus lines GBL81 and GBL82.

Also, the semiconductor device 24 according to the second embodiment, as shown in FIG. 14, connecting points Q1, Q2, Q3, . . . , Q8 between the gate extracting lines EBL1, EBL2, EBL3, . . . , EBL8 and the designated gate bus lines GBL1, GBL2, GBL3, . . . , GBL8 is shifted from the center of each the unit FET cells FET1, FET2, FET3, . . . , FET8 having multi-fingers, respectively, and the number of the gate fingers connected to one side of the respective connecting points Q1, Q2, Q3, . . . , Q8 is more than the number of the gate fingers connected to another side of the respective connecting points Q1, Q2, Q3, . . . , Q8.

In the semiconductor device 24 according to the second embodiment, the respective gate extracting lines EBL1, EBL2, EBL3, . . . , EBL8 become a load for the loop oscillation in one cell, since the respective gate extracting lines EBL1, EBL2, EBL3, . . . , EBL8 are connected at the respective connecting points Q1, Q2, Q3, . . . , Q8 dislocated from the respective cross over points between the center lines of the respective unit FET cells FET1, FET2, FET3, . . . , FET8 having multi-fingers and the loop in one cell. Accordingly, the oscillating condition is not satisfied and therefore the loop oscillation in one cell can be suppressed.

Also, as shown in FIG. 14, in the semiconductor device 24 according to the second embodiment, the plurality of unit FET cells FET1, FET2, FET3, . . . , FET8 having multi-fingers include: a substrate 110; a gate finger electrode 124, a source finger electrode 120, and a drain finger electrode 122 configured to be disposed on a first surface of the substrate 110, and configured to have a plurality of fingers, respectively; and gate terminal electrodes G1, G2, . . . , G8, source terminal electrodes S11, S12, S21, S22, S31, S32, . . . , S81, and S82 and drain terminal electrodes D1, D2, D3, . . . , D8 configured to be disposed on the first surface of the substrate 100 and configured to tie the plurality of the fingers for every the gate finger electrode 124, the source finger electrode 126, and the drain finger electrode 122, respectively. Each of the respective gate terminal electrodes G1, G2, . . . , G8 is connected to an input matching circuit by a bonding wire etc., and each of the respective drain terminal electrodes D1, D2, . . . , D8 is connected to an output matching circuit by a bonding wire etc.

Also, in the semiconductor device 24 according to the second embodiment, the respective gate extracting lines EBL1, EBL2, EBL3, . . . , EBL8 connect between the respective designated gate bus lines GBL1, GBL2, GBL3, . . . , GBL8, and the respective gate terminal electrodes G1, G2, G3, . . . , G8.

Also, as shown in FIG. 14, the semiconductor device 24 according to the second embodiment may include: VIA holes SC11, SC12, SC21, SC22, SC31, SC32, . . . , SC81, and SC82 configured to be disposed at lower parts of the source terminal electrodes S11, S12, S21, S22, S31, S32, . . . , S81, and S82, respectively; and a ground electrode (not shown) configured to be disposed on a second surface of opposite side of the first surface of the substrate 110, and configured to be connected via the VIA holes SC11, SC12, SC21, SC22, SC31, SC32, . . . , SC81, and SC82 with the source terminal electrodes S11, S12, S21, S22, S31, S32, . . . , S81, and S82, respectively.

The source terminal electrodes S11, S12, S21, S22, . . . , S81, and S82 are connected to the ground electrode via barrier metal layers (not shown) formed on surfaces of internal walls of the VIA holes SC11, SC12, SC21, SC22, . . . , SC81, and SC82, respectively, and via filling metal layers (not shown) formed on the barrier metal layers configured to fill the VIA holes, respectively.

Also, In the semiconductor device 24 according to the second embodiment, as shown in FIG. 14, the unit FET cells FET1, FET2, FET3, . . . , FET8 having multi-fingers may be connected in parallel.

Furthermore, in the semiconductor device 24 according to the second embodiment, as shown in FIG. 14, balancing resistances RG12, RG23, RG34, . . . , RG78 between cells for suppressing a loop oscillation between cells may be disposed respectively between the designated gate bus lines GBL1 and GBL2, between GBL2 and GBL3, between GBL3 and GBL4, . . . , between GBL7 and GBL8 of the unit FET cells FET1, FET2, FET3, . . . , FET8 having multi-fingers which are mutually adjoining.

In addition, in the semiconductor device 24 according to the second embodiment, the pattern width W1 in longitudinal direction of the gate finger electrode 124, the source finger electrode 120, and the drain finger electrode 122 is set up to be shorter as operating frequency becomes high such as microwave/millimeter wave/submillimeter wave. For example, the pattern width W1 is about 100 μm in the microwave band, and is about 25 μm to 50 μm in the millimeter wave band.

Also, the width of the source finger electrode 120 is about 40 μm, for example, and the pattern width W2 of the source terminal electrode S11, S12, S21, S22, . . . , S101, and 5102 is about 100 μm, for example. Also, the pattern length L1 of the drain terminal electrode D1, D2, D3, . . . , D8 is about 100 μm, for example. Yet also, the formation width of the VIA holes SC11, SC12, SC21, SC22, . . . , SC101, and SC102 is about 10 μm to about 40 μm, for example.

### Second Comparative Example

A schematic planar pattern configuration of a semiconductor device 24a according to a second comparative example is expressed as shown in FIG. 2. In the semiconductor device 24a according to the second comparative example, each of the FET cells FET1, FET2, FET3, . . . , FET8 is equally divided into two parts, each of the balancing resistances RG1, RG2, RG3, . . . , RG8 in one cell is inserted between gate inputs of each the ½ FET cell divided into two parts, and thereby the loop oscillation in one cell can be suppressed. More specifically, the balancing resistance RG1 in one cell, RG2, RG3, . . . , RG8 are disposed between the designated gate bus lines GBL11 and GBL12, between GBL21 and GBL22, between GBL31 and GBL32, . . . , and between GBL81 and GBL82, respectively. However, according to the second comparative example, as shown in FIG. 2, space for disposing the balancing resistances RG1, RG2, RG3, . . . , RG8 in one cell is required, and therefore an area of the semiconductor device 24a is increased.

### (Element Structure)

Schematic cross-sectional structure examples 1-4 taken in the line I-I of FIG. 14B, which are the element structures of the semiconductor device 24 according to the second embodiment, are expressed as shown in FIG. 3 to FIG. 6, respectively, as well as the element structure of the semiconductor device 24 according to the first embodiment. Hereinafter, the duplicate explanation with the element structure of the semiconductor device 24 according to the first embodiment will be omitted.

### (Loop Oscillation in One Cell)

In the semiconductor device according to the second embodiment, a schematic circuit configuration for explaining a loop oscillation in one cell is expressed as shown in FIG. 7A, and a schematic circuit configuration for explaining suppression effect of the loop oscillation in one cell is expressed as shown in FIG. 7B.

A unit FET cell having multi-fingers is expressed by ½ FET cells A01 and A02, as shown in FIG. 7A and FIG. 7B. As shown in FIG. 7A and FIG. 7B, a loop LP1 in one cell includes: ½ FET cells A01 and A02 used in a pair; a designated gate bus line GBL1 configured to connect a gate of the ½ FET cell A01 and a gate of the ½ FET cell A02; and a designated drain bus line DBL1 configured to connect a drain of the ½ FET cell A01 and a drain of the ½ FET cell A02.

In the example of FIG. 7A, a gate extracting line EBLG1 and a drain extracting line EBLG1 are disposed on a center line CL of the loop LP1 in one cell composed of the ½ FET cells A01 and A02, and a cross over point P between the center line CL and the loop LP1 in one cell is coincided with a connecting point Q1 between the gate extracting line EBLG1 and the designated gate bus line GBL1.

On the other hand, in the example of FIG. 7B, the drain extracting line EBLD1 is disposed on the center line CL of the loop LP1 in one cell composed of the ½ FET cells A01 and A02, and the connecting point Q1 between the gate extracting line EBLG1 and the designated gate bus line GBL1 is disposed at a position shifted in a ½ FET cell A01 direction on the loop LP1 in one cell from the cross over point P between the center line CL and the loop LP1 in one cell.

In the example of FIG. 7A, the loop LP1 in one cell composes an oscillating loop and becomes a node of the standing wave on the cross over point P between the center line CL of the loop LP1 in one cell composed of the ½ FET cells A01 and A02 and the loop LP1 in one cell, and an outside observed from the crossover point P appears as total reflection. As a result, the gate extracting line EBLG1 connected to the cross over point P does not become the load for the loop oscillation in one cell. That is, the loop oscillation in one cell occurs.

On the other hand, as shown in FIG. 7B, since the gate extracting line EBLG1 connected to the connection point Q1 dislocated from the cross over point P between the center line CL of the loop LP1 in one cell composed of the ½ FET cells A01 and A02 and the loop LP1 in one cell becomes the load for the loop oscillation in one cell, the oscillating condition is not satisfied, and therefore the loop oscillation in one cell can be suppressed.

### (Circuit Configuration of Semiconductor Amplifier)

A configuration of a schematic equivalent circuit of a semiconductor amplifier to which the semiconductor device according to the second embodiment is applied is expressed as shown in FIG. 8. In FIG. 8, reference numerals Qa and Qb denote source grounded ½ FET cells, respectively, and the respective source grounded ½ FET cells include a gate terminal electrode G, a drain terminal electrode D, and a source terminal electrode S. The ½ FET cells Qa and Qb are equivalent to cells after the unit FET cell having multi-fingers is divided into two parts, and correspond to the ½ FET cells A01 and A02 in FIG. 7A and FIG. 7R, respectively. Moreover, in FIG. 8, reference numeral 202 denotes an input terminal of the amplifier, reference numeral 203 denotes an output terminal of the amplifier, reference numeral 210 denotes an input matching circuit, and reference numeral 211 denotes an output matching circuit.

Reference numerals 204, 205, 206, 207, 208, and 209 denotes transmission lines, respectively, and an amplifier composed to connect the transmission lines 205, 206, 207 and 208, a bonding wire 218, and the source grounded ½ FET cells Qa or Qb in this order is connected in parallel between two couples of the transmission lines 204 and 209. That is, the transmission line from the transmission line 204 connected to the input terminal 202 branches to two-way at point A, and then two couples of the transmission lines 205 and 206 connected in series are connected to a gate terminal G of the ½ FET cell Qa or Qb in series via the bonding wire 218. Furthermore, from drain terminal D of the ½ FET cell Qa or Qb, the transmission lines 207 and 208 are also connected in series via the bonding wire 218, other ends of two couples of the transmission lines 208 are connected in common to one end of the transmission line 209 at point B, and other end of the transmission line 209 is connected to the output terminal 203. The input matching circuit 210 is composed of the above-mentioned transmission lines 204, 205, and 206, respectively, and the output matching circuit 211 composed of the above-mentioned transmission lines 207, 208, and 209, respectively.

In the amplifier, a loop circuit 212 in one cell is composed of the transmission lines 205, 206, 207 and 208 and the ½ FET cells Qa and Qb configured to operate in parallel. Reference numeral 213 denotes an equivalent resistance circuit. The equivalent resistance circuit 213 is composed of a transmission line 214 for connection and a balance equivalent resistance 215 in one cell, and is connected to a predetermined position which opposes in the input matching circuit of the above-mentioned loop circuit 212 in one cell.

Hereinafter, operation will be explained. In FIG. 8, a fundamental wave, i.e., a signal component of frequency f₀, is input from the input terminal 202, and then is distributed at the point A to be input into the respective ½ FET cells Qa and Qb connected in parallel. The signals amplified in the respective ½ FET cells Qa and Qb are synthesized at the point B, and then the synthesized signal is output from the output terminal 203.

In the semiconductor amplifier to which the semiconductor device according to the second embodiment is applied, a loop gain calculating circuit in one cell configured to attach a circulator to the input side of the loop circuit 212 in one cell is expressed as shown in FIG. 9A, and a loop gain calculating circuit in one cell configured to attach a circulator to the output side of the loop circuit 212 in one cell is expressed as shown in FIG. 9B.

Here, in the loop circuit 212 in one cell shown in FIG. 9A and FIG. 9B, a loop oscillating condition in one cell is expressed by the following formulas (1) and (2).

|B1/A1|>=1 and ∠(B1/A1)=2 nπ (1)

|B2/A2|>=1 and ∠(B2/A2)=2 mπ (2)

where m and n are integers.

In this case, the terms A1 and B1 indicate an input traveling wave in the input side and an output traveling wave from the loop circuit 212 in one cell, respectively, in the case of attaching tentatively the ideal circulator 220 to the input side of the loop circuit 212 in one cell shown in FIG. 9A, as paper calculating. Also, the terms A2 and B2 indicate an input traveling wave in the output side and an output traveling wave from the loop circuit 212 in one cell, respectively, in the case of attaching tentatively the ideal circulator 220 to the output side of the loop circuit 212 in one cell shown in FIG. 9B.

In order for an oscillation to occur, it is required to satisfy ∠(B1/A1)=2 nπ. The above state corresponds to a state where a standing wave stands between the point A and the point B. At the point A and the point B, the output traveling wave B1 and the input traveling wave A1 are canceled each other, and then there is no voltage amplitude, that is, it becomes a position of a node of the standing wave. The node of the standing wave corresponds to a position with a voltage of 0 V, and the position with the voltage of 0 V becomes equivalent to a state where it is grounded.

Therefore, as already explained in FIG. 7A, the transmission line composed of the gate extracting line EBLG1 connected to the node of the standing wave, i.e., the position grounded, does not appear as a load for the frequency component in which the oscillation has occurred in the loop LP1 in one cell.

On the other hand, voltage has occurred on the loop in one cell except the position acting as the node. Therefore, as already explained in FIG. 7B, the transmission line composed of the gate extracting line EBLG1 connected except the node appears as the load for the frequency component in which the oscillation has occurred in the loop LP1 in one cell, and its phase changes. As a result, ∠(B1/A1)=2 nπ is not satisfied. That is, since the oscillating condition is not satisfied, the loop oscillation in the multi-finger FET cell can be suppressed.

In the semiconductor device according to the second embodiment, the value of the balance equivalent resistance 215 in one cell which is a level that the suppression effect of the loop oscillation in the unit FET cell having multi-fingers occurs is the same grade as the impedance of the transmission line composed of gate extracting line EBLG1. Accordingly, in the semiconductor device according to the second embodiment, the loop oscillation can be suppressed without disposing the balancing resistance RG1 in one cell as the second comparative example shown in FIG. 2, and the area is also not increased.

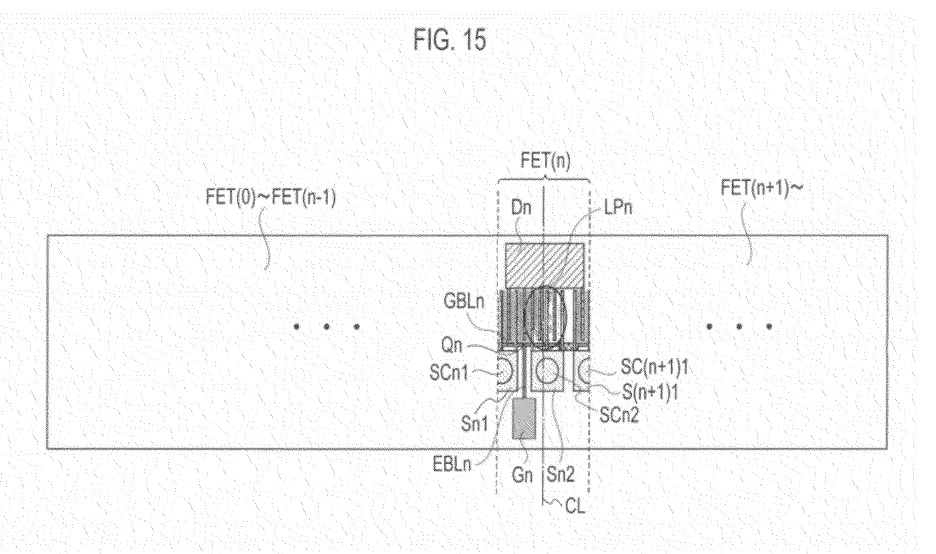

In the semiconductor device according to the second embodiment, a schematic circuit configuration for explaining the suppression effect of the loop oscillation in one cell with focusing attention on a specific FET cell FET (n) is expressed as shown in FIG. 15.

When focusing attention on the bundle of the drain fingers connected to the drain terminal electrode Dn, the loop in one cell (closed loop) which can be composed within the bundle of the drain fingers is expressed in LPn. Therefore, the connecting point Qn between the gate extracting line EBLn connected to the gate terminal electrode Gn and the designated gate bus line GBLn is dislocated from the center line CL and shifted from the node of the standing wave of the loop oscillation in one cell. Accordingly, since the designated gate bus line GBLn connected to the connecting point Qn dislocated from the center line CL becomes the load for the loop oscillation frequency component in one cell, the oscillating condition is not satisfied, and therefore the loop oscillation in one cell can be suppressed.

According to the semiconductor device according to the second embodiment, as for the unit FET cells FET1, FET2, FET3, . . . , FET8 having multi-fingers, although the way the gate fingers are bundled is shifted against the way the drain fingers are bundled, such configuration is achievable because the drain terminal electrode is divided into the drain terminal electrodes D1, D2, D3, . . . , D8. It is because, in the case of the configuration that the drain terminal electrode is disposed as a common electrode, even if the way the gate fingers are bundled is shifted against the way the drain fingers are bundled, the connecting point Qn between the gate extracting line EBLn and the designated gate bus line GBLn becomes the node of the standing wave of the loop oscillation in one cell. As a result, the designated gate bus line GBLn does not become the load for the loop oscillation frequency component in one cell, and therefore the oscillating condition is satisfied.

According to the semiconductor device according to the second embodiment, the loop oscillation in the multi-finger FET cell can be suppressed, and the increase of chip area can also be suppressed.

### Third Embodiment

### Plane Pattern Configuration

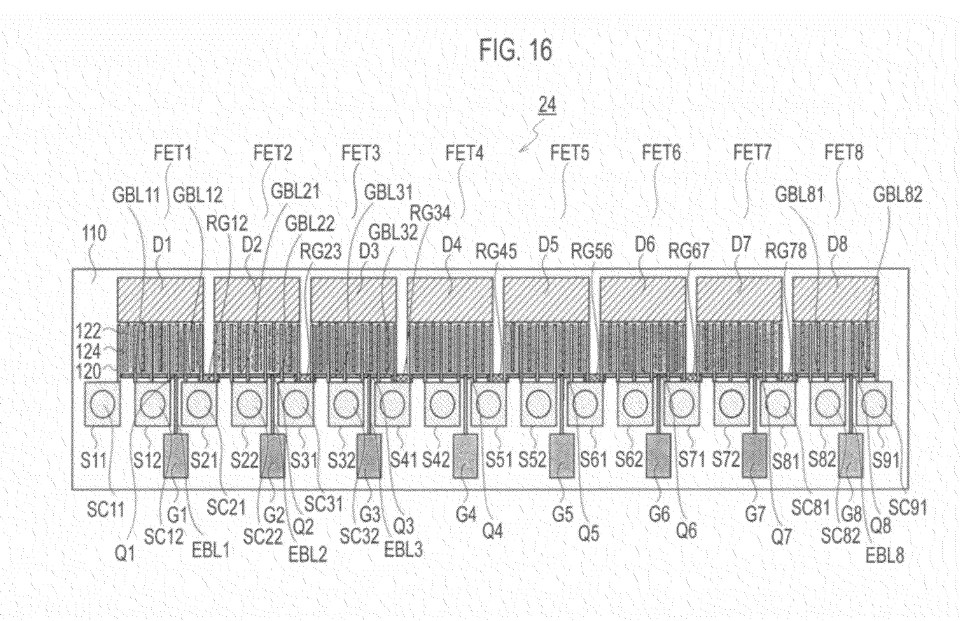

A schematic plane pattern configuration of a semiconductor device 24 according to a third embodiment is expressed as shown in FIG. 16.

As shown in FIG. 16, the semiconductor device 24 according to the third embodiment includes: unit FET cells FET1, FET2, FET3, . . . , FET8 having multi-fingers composed of parallel connection of unit fingers; designated gate bus lines GBL1, GBL2, GBL3, . . . , GBL8 configured to connect the gate fingers of the unit FET cells FET1, FET2, FET3, . . . , FET8 having multi-fingers in parallel, respectively; and gate extracting lines EBL1, EBL2, EBL3, . . . , EBL8 configured to be connected to the designated gate bus lines GBL1, GBL2, GBL3, . . . , GBL8, respectively. As for the unit FET cells FET1, FET2, FET3, . . . , FET8 having multi-fingers, the way source fingers are bundled is shifted against the way the drain fingers are bundled. In this case, the designated gate bus line GBL1 is expressed by connection between the designated gate bus lines GBL11 and GBL12, the designated gate bus line GBL2 is expressed by connection between the designated gate bus lines GBL21 and GBL22, the designated gate bus line GBL3 is expressed by connection between the designated gate bus lines GBL31 and GBL32, . . . , and the designated gate bus line GBL8 is expressed by connection between the designated gate bus lines GBL81 and GBL82.

Also, in the semiconductor device 24 according to the third embodiment, as shown in FIG. 16, connecting points Q1, Q2, Q3, . . . , Q8 between the gate extracting lines EBL1, EBL2, EBL3, . . . , EBL8 and the designated gate bus lines GBL1, GBL2, GBL3, . . . , GBL8 are shifted from centers in the unit FET cells FET1, FET2, FET3, . . . , FET8 having multi-fingers, respectively, and thereby the number of the gate fingers connected to one side of the respective connecting points Q1, Q2, Q3, . . . , Q8 is more than the number of the gate fingers connected to another side of the respective connecting points Q1, Q2, Q3, . . . , Q8.

In the semiconductor device 24 according to the third embodiment, the respective gate extracting lines EBL1, EBL2, EBL3, . . . , EBL8 become a load for the loop oscillation in one cell since the respective gate extracting lines EBL1, EBL2, EBL3, . . . , EBL8 are connected at the respective connecting points Q1, Q2, Q3, . . . , Q8 dislocated from the respective cross over points between the respective center lines of the unit FET cells FET1, FET2, FET3, . . . , FET8 having multi-fingers and the loop in one cell, and the oscillating condition is not satisfied, and therefore the loop oscillation in one cell can be suppressed.

Also in the semiconductor device 24 according to the third embodiment, the basic element composition is the same as that of the second embodiment, and therefore it can apply the configuration examples 1-4 according to the second embodiment shown in FIG. 3 to FIG. 6, for example. Duplicating explanation is omitted since other configurations are the same as that of the second embodiment.

As shown in FIG. 16, although the semiconductor device according to the third embodiment has the configuration into which the drain terminal electrodes D1, D2, D3, . . . , D8 are divided, the drain terminal electrodes D1, D2, D3, . . . , D8 may be composed as a common electrode since the way the source fingers are bundled is shifted against the way the drain fingers are bundled, in the unit FET cells FET1, FET2, FET3, . . . , FET8 having multi-fingers. In the configuration on which the drain terminal electrodes are disposed as a common electrode, the way the source fingers are bundled is shifted against the way the drain fingers are bundled, and thereby the connecting point Qn between the gate extracting line EBLn and the designated gate bus line GBLn is dislocated from the node of the standing wave of the loop oscillation in one cell. As a result, since the designated gate bus line GBLn becomes load for the loop oscillation frequency component in one cell, the oscillating condition is not satisfied, and therefore the loop oscillation in one cell can be suppressed.

According to the semiconductor device according to the third embodiment, the loop oscillation in the multi-finger FET cell can be suppressed, and the increase of chip area can also be suppressed.

### Fourth Embodiment

### Plane Pattern Configuration

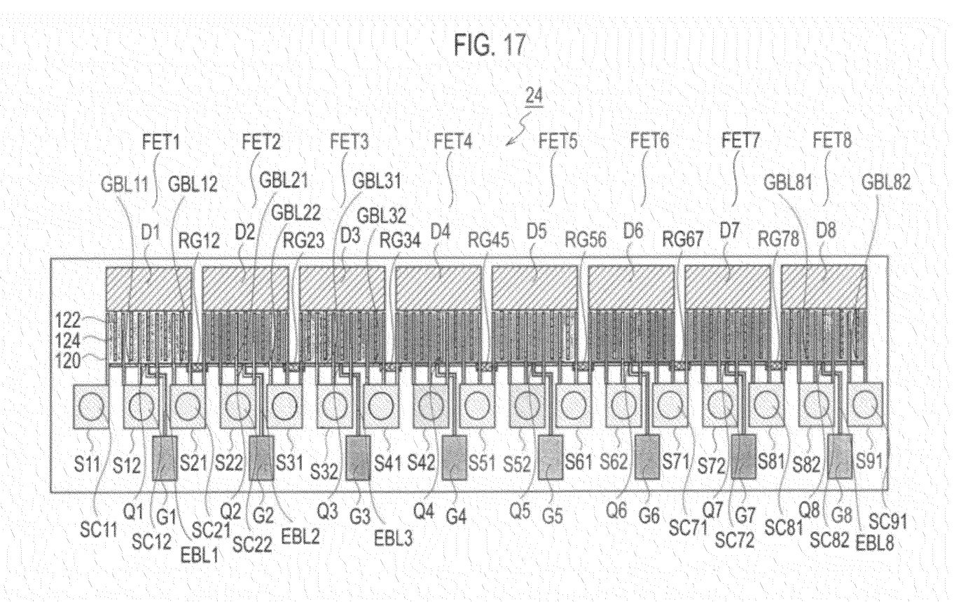

A schematic plane pattern configuration of a semiconductor device according to a fourth embodiment is expressed as shown in FIG. 17.

The semiconductor device 24 according to the fourth embodiment, as well as that of the third embodiment, includes: unit FET cells FET1, FET2, FET3, . . . , FET8 having multi-fingers composed of parallel connection of unit fingers; designated gate bus lines GBL1, GBL2, GBL3, . . . , GBL8 configured to connect the gate fingers of the unit FET cells FET1, FET2, FET3, . . . , FET8 having multi-fingers in parallel, respectively; and gate extracting lines EBL1, EBL2, EBL3, . . . , EBL8 configured to be connected to the designated gate bus lines GBL1, GBL2, GBL3, . . . , GBL8, respectively. As for the unit FET cells having multi-fingers, the way source fingers are bundled is shifted against the way the gate fingers are bundled. In this case, the designated gate bus line GBL1 is expressed by connection between the designated gate bus lines GBL11 and GBL12, the designated gate bus line GBL2 is expressed by connection between the designated gate bus lines GBL21 and GBL22, the designated gate bus line GBL3 is expressed by connection between the designated gate bus lines GBL31 and GBL32, . . . , and the designated gate bus line GBL8 is expressed by connection between the designated gate bus lines GBL81 and GBL82.

Also, the semiconductor device 24 according to the fourth embodiment, as shown in FIG. 17, connecting points Q1, Q2, Q3, . . . , Q8 between the gate extracting lines EBL1, EBL2, EBL3, . . . , EBL8 and the designated gate bus lines GBL1, GBL2, GBL3, . . . , GBL8 are disposed on centers in the unit FET cells FET1, FET2, FET3, . . . , FET8 having multi-fingers, respectively, and thereby the number of the gate fingers connected to one side of the respective connecting points Q1, Q2, Q3, . . . , Q8 is equal to the number of the gate fingers connected to another side of the respective connecting points Q1, Q2, Q3, . . . , Q8. Therefore, fate power feeding to the designated gate bus lines GBL1, GBL2, GBL3, . . . , GBL8 can be equalized via the gate terminal electrodes G1, G2, . . . , G8 connected to the gate extracting lines EBL1, EBL2, EBL3, . . . , EBL8, in each of the cells of the unit FET cells FET1, FET2, FET3, . . . , FET8 having multi-fingers.

In the semiconductor device 24 according to the fourth embodiment, the respective gate extracting lines EBL1, EBL2, EBL3, . . . , EBL8 become a load for the loop oscillation in one cell since the respective gate extracting lines EBL1, EBL2, EBL3, . . . , EBL8 are connected at the respective connecting points Q1, Q2, Q3, . . . , Q8 dislocated from the respective cross over points between the respective center lines of the unit FET cells FET1, FET2, FET3, . . . , FET8 having multi-fingers and the loop in one cell. Accordingly, the oscillating condition is not satisfied, and therefore the loop oscillation in one cell can be suppressed.

Also in the semiconductor device 24 according to the fourth embodiment, the basic element composition is the same as that of the second embodiment, and therefore it can apply the configuration examples 1-4 according to the second embodiment shown in FIG. 3 to FIG. 6, for example. Duplicating explanation is omitted since other configurations are the same as that of the third embodiment.

As shown in FIG. 17, although the semiconductor device according to the fourth embodiment has the configuration into which the drain terminal electrodes D1, D2, D3, . . . , D8 are divided, the drain terminal electrodes D1, D2, D3, . . . , D8 may be composed as a common electrode since the way the source fingers are bundled is shifted against the way the gate fingers are bundled, in the unit FET cells FET1, FET2, FET3, . . . , FET8 having multi-fingers.

According to the semiconductor device according to the fourth embodiment, the loop oscillation in the multi-finger FET cell can be suppressed, and the increase of chip area can also be suppressed.

According to the semiconductor devices according to the embodiments described herein, the loop oscillation in the multi-finger FET cell can be suppressed, and the increase of chip area can also be suppressed, in a high frequency semiconductor device having a microwave band mainly.

### The Other Embodiments

While certain embodiments have been described, these embodiments have been presented by way of examples only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

In addition, as a basic element of the semiconductor devices according to the embodiments described herein, it needless to say that not only the FET and HEMT but also amplifying elements, such as a Laterally Doped Metal-Oxide-Semiconductor Field Effect Transistor (LDMOS) and a Hetero-junction Bipolar Transistor (HBT), and a Micro Electro Mechanical Systems (MEMS) element, etc. are applicable.

Such being the case, the embodiments described herein cover a variety of embodiments, whether described or not.

What is claimed is:

1. A semiconductor device comprising:
a unit FET cell having multi-fingers composed of parallel connection of a unit finger;
a designated gate bus line configured to connect gate fingers of the unit FET cell having multi-fingers in parallel; and
a gate extracting line configured to be connected to the designated gate bus line, wherein
a connecting point between the gate extracting line and the designated gate bus line is shifted from a center in the unit FET cell having multi-fingers, and thereby the number of the gate fingers connected to one side of the connecting point is more than the number of the gate fingers connected to another side of the connecting point.

2. The semiconductor device according to claim 1, wherein the unit FET cell having multi-fingers comprises:
a substrate;
a gale finger electrode, a source finger electrode, and a drain finger electrode configured to be disposed on a first surface of the substrate, and configured to have a plurality of fingers, respectively; and
a gate terminal electrode, a source terminal electrode, and a drain terminal electrode configured to be disposed on the first surface of the substrate, and configured to tie a plurality of fingers, respectively for every the gate finger electrode, the source finger electrode, and the drain finger electrode.

3. The semiconductor device according to claim 2, wherein
the gate extracting line connects between the designated gate bus line and the gate terminal electrode.

4. The semiconductor device according to claim 1 further comprising:
a VIA hole configured to be disposed at a lower part of the source terminal electrode; and
a ground electrode configured to be disposed on a second surface of an opposite side of the first surface of the substrate, and configured to be connected to the source terminal electrode via the VIA hole.

5. The semiconductor device according to claim 1, wherein
the unit FET cell having multi-fingers is connected in parallel.

6. The semiconductor device according to claim 5, wherein
a balancing resistance between cells is disposed between the designated gate bus lines of the unit FET cells having multi-fingers mutually adjoining.

7. The semiconductor device according to claim 2, wherein the substrate includes one selected from the group consisting of an SiC substrate, a GaAs substrate, a GaN substrate, a substrates in which a GaN epitaxial layer is formed on an SiC substrate, a substrate in which the GaN epitaxial layer is formed on the Si substrate, a substrate in which the heterojunction epitaxial layer composed of GaN/GaAlN is formed on the SiC substrate, a substrate in which the GaN epitaxial layer is formed on the sapphire substrate, a sapphire substrate or a diamond substrate, and a semi-insulating substrate.

8. A semiconductor device comprising:
a unit FET cell having multi-fingers composed of parallel connection of a unit finger;
a designated gate bus line configured to connect gate fingers of the unit FET cell having multi-fingers in parallel; and
a gate extracting line configured to be connected to the designated gate bus line, wherein
as for the unit FET cell having multi-fingers, one of the way gate fingers are bundled and the way source fingers are bundled is shifted against the way the drain fingers are bundled.

9. The semiconductor device according to claim 8, wherein
a connecting point between the gate extracting line and the designated gate bus line is shifted from a center in the unit FET cell having multi-fingers, and thereby the number of the gate fingers connected to one side of the connecting point is more than the number of the gate fingers connected to another side of the connecting point.

10. The semiconductor device according to claim 8, wherein
a connecting point between the gate extracting line and the designated gate bus line is shifted from a center in the unit FET cell having multi-fingers, and thereby the number of the gate fingers connected to one side of the connecting point is equal to the number of the gate fingers connected to another side of the connecting point.

11. The semiconductor device according to claim 8, wherein the unit FET cell having multi-fingers comprises:
a substrate;
a gate finger electrode, a source finger electrode, and a drain finger electrode configured to be disposed on a first surface of the substrate, and configured to have a plurality of fingers, respectively; and
a gate terminal electrode, a source terminal electrode, and a drain terminal electrode configured to be disposed on the first surface of the substrate, and configured to tie a plurality of fingers, respectively for every the gate finger electrode, the source finger electrode, and the drain finger electrode.

12. The semiconductor device according to claim 11, wherein
the gate extracting line connects between the designated gate bus line and the gate terminal electrode.

13. The semiconductor device according to claim 8 further comprising:
a VIA hole configured to be disposed at a lower part of the source terminal electrode; and
a ground electrode configured to be disposed on a second surface of an opposite side of the first surface of the substrate, and configured to be connected to the source terminal electrode via the VIA hole.

14. The semiconductor device according to claim 8, wherein

15. The semiconductor device according to claim 8, wherein
the unit FET cell having multi-fingers is connected in parallel.

16. The semiconductor device according to claim 14, wherein
a balancing resistance between cells is disposed between the designated gate bus lines of the unit FET cells having multi-fingers mutually adjoining.

17. The semiconductor device according to claim 11, wherein
the substrate includes one selected from the group consisting of an SiC substrate, a GaAs substrate, a GaN substrate, a substrates in which a GaN epitaxial layer is formed on an SiC substrate, a substrate in which the GaN epitaxial layer is formed on the Si substrate, a substrate in which the heterojunction epitaxial layer composed of GaN/GaAlN is formed on the SiC substrate, a substrate in which the GaN epitaxial layer is formed on the sapphire substrate, a sapphire substrate or a diamond substrate, and a semi-insulating substrate.
